(19) United States
(12) Patent Application Publication
(10) Pub. No.: US 2026/0123393 A1
(43) Pub. Date: Apr. 30, 2026

(54) FOOTING FOR CONDUCTIVE LINE OF SEMICONDUCTOR DEVICE

(71) Applicant: Micron Technology, Inc., Boise, ID (US)

(72) Inventors: Jun Ho LEE, Meridian, ID (US); Byung Yoon KIM, Boise, ID (US); Inchan HWANG, Meridian, ID (US); Russell A. BENSON, Boise, ID (US)

(21) Appl. No.: 19/318,680

(22) Filed: Sep. 4, 2025

Related U.S. Application Data
(60) Provisional application No. 63/713,771, filed on Oct. 30, 2024.

(51) Int. Cl. H01L 23/528; G11C 5/06; H01L 21/768; H10B 12/00; H10B 53/10; H10B 53/40

(52) U.S. Cl. CPC H10W 20/435; H10W 20/033; H10W 20/038; H10W 20/081; H10W 20/095; H10W 20/096; H10W 20/097; G11C 5/063; H10B 12/482; H10B 12/50; H10B 53/10; H10B 53/40

(57) ABSTRACT

Implementations described herein relate to various structures, integrated assemblies, and memory devices. In some implementations, an apparatus includes a semiconductive region, an insulative region that is adjacent to the semiconductive region, and a conductive line that extends across the semiconductive region and at least a portion of the insulative region. The apparatus includes a contact structure that conjoins with the conductive line and that electrically couples the conductive line with the semiconductive region. The apparatus includes a footing structure that conjoins with the conductive line and that penetrates into the insulative region to anchor the conductive line with the insulative region.

### CROSS-REFERENCE TO RELATED APPLICATION

This patent application claims priority to U.S. Provisional Patent Application No. 63/713,771, filed on Oct. 30, 2024, entitled “FOOTING FOR CONDUCTIVE LINE OF SEMICONDUCTOR DEVICE,” and assigned to the assignee hereof. The disclosure of the prior application is considered part of and is incorporated by reference into this patent application.

### TECHNICAL FIELD

The present disclosure generally relates to semiconductor devices and methods of forming semiconductor devices. For example, the present disclosure relates to a footing for a conductive line of a semiconductor device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell described herein.

FIGS. 2A and 2B are diagrammatic views of an example semiconductor device described herein.

FIG. 3 is a flowchart of an example method of forming an integrated assembly or memory device having a footing structure.

FIGS. 4A-4D are diagrammatic views showing formation of footing structures for a conductive line at stages of an example process of forming the footing structures.

FIG. 5 is a diagrammatic view of an example memory device described herein.

### DETAILED DESCRIPTION

In the evolving landscape of semiconductor device fabrication, a persistent challenge is associated with the miniaturization of conductive lines (e.g., digit lines), especially as the industry progresses toward ever smaller technology nodes. High aspect ratio conductive lines, which are integral to the layouts of various semiconductor devices, are particularly susceptible to structural instabilities such as toppling risks as their dimensions shrink. A toppling risk may correspond to a conductive line leaning or bending, jeopardizing the reliability and functionality of the semiconductor device. As conductive lines serve as critical pathways for electrical signals, their toppling can lead to significant performance issues or even device failure.

Toppling of these conductive lines is exacerbated by the high aspect ratios that have become commonplace in advanced semiconductor devices. Conventional designs and manufacturing techniques have not adequately addressed the challenges involved in preventing such toppling while continuing the trend of scaling down feature sizes. Thus, there is a technical problem in providing a structural design solution that can reinforce high aspect ratio conductive lines and prevent their toppling without imposing additional processing steps or escalating production costs, thereby enabling tighter array pitches for future technology nodes.

Some implementations described herein provide a structure that enhances the mechanical stability of high aspect ratio conductive lines. In some implementations, an apparatus includes an array of semiconductive regions (e.g., active areas of a memory array) and an adjacent insulative region (e.g., a shallow trench isolation region). The apparatus features a conductive line (e.g., a digit line) that traverses both the array of semiconductive regions and a portion of the insulative region, with contact structures facilitating electrical connectivity between the conductive line and the semiconductive regions. Additionally, the structure integrates a set of footing structures that penetrate the insulative region, providing a robust anchor to the conductive line and significantly reducing the risk of toppling during manufacturing and operation.

The structure provides technical benefits by preventing conductive line toppling in semiconductor devices with fine pitch arrays, thereby preserving the structural integrity without necessitating additional complex manufacturing processes, which could otherwise escalate production costs. The incorporation of footing structures that extend into the insulative region effectively secures the conductive lines, enabling denser array pitches and higher integration levels that are essential for advancing semiconductor technology nodes.

In these ways, the quality and/or reliability of the semiconductor device is improved. Since the quality and/or the reliability of the semiconductor device are improved, an amount of resources used to support a market consuming the semiconductor device (e.g., raw materials, semiconductor manufacturing tools, labor, and/or computing resources) is reduced, thus maintaining industry competitiveness without imposing extra resource expenditure.

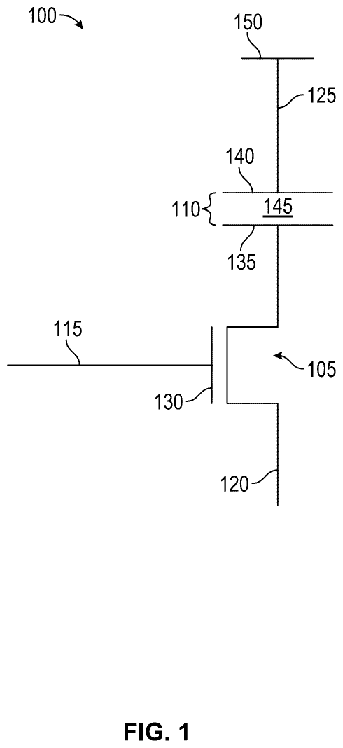

FIG. 1 is a circuit diagram of an example memory cell 100 described herein. In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the digit line 120 to the bottom electrode 135 of the capacitor 110. A state of the memory cell 100 may then be written or read via the digit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the digit line 120).

For a ferroelectric capacitor, the applied voltage creates an electric field, and the atoms in the ferroelectric material of the insulator 145 respond to the electric field to become arranged in a particular state (e.g., a particular orientation or polarization), which is representative of a data state (e.g., a logic “0” state or a logic “1” state). In some implementations, data may be stored using the capacitor 110 by controlling a voltage difference and/or a polarity difference of the capacitor 110 (e.g., of the insulator 145 between the bottom electrode 135 and the top electrode 140). For example, a voltage of the cell plate 150 and the digit line 120 may be controlled. In some implementations, a negative polarity of the insulator 145 as compared to the cell plate 150 results in a logic “0” state being stored in the capacitor 110, and a positive polarity of the insulator 145 as compared to the cell plate 150 results in a logic “1” state being stored in the capacitor 110. For a linear dielectric capacitor or a paraelectric capacitor, the cell plate 150 may grounded, and the capacitor 110 may be charged by applying a voltage to the bottom electrode 135 via the digit line 120.

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

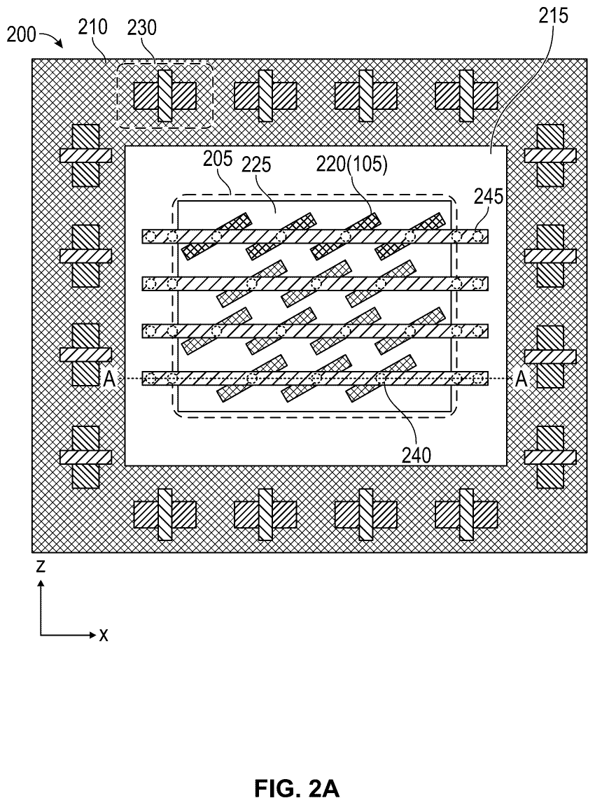

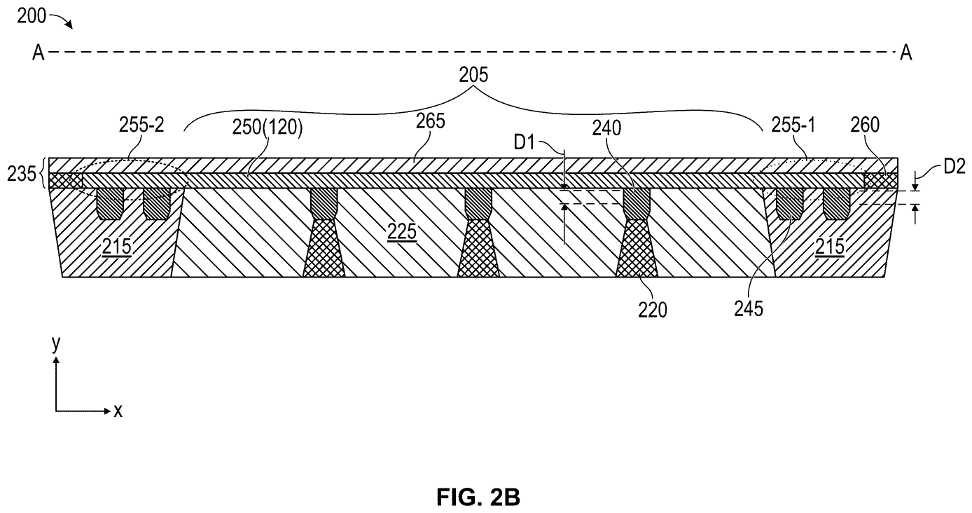

As described in greater detail in connection with FIGS. 2A-5, a semiconductor device may include a memory array having multiples of the memory cell 100, including multiples of the transistor 105 and/or the digit line 120. The semiconductor device may further include an integrated circuit region that surrounds the memory array and an isolation region (e.g., a shallow trench isolation region) between the memory array and the integrated circuit region.

In some implementations, the digit line 120 may be a multi-layer structure that includes a conductive line that extends across the memory array, where contact structures electrically (and mechanically) couple the conductive line with the transistor 105 (e.g., active areas corresponding to channels of the transistor 105). To increase a robustness of the digit line 120, footing structures may anchor end regions of the conductive line to the isolation region and prevent toppling of the conductive line (and/or the digit line 120) during and/or after formation of the semiconductor device.

As indicated above, FIG. 1 is provided as an example. Other examples may differ from what is described with respect to FIG. 1.

FIGS. 2A and 2B are diagrammatic views of an example semiconductor device 200 described herein. FIG. 2A is a plan view of the semiconductor device 200 and FIG. 2B is a side section view of the semiconductor device 200 along the section line A-A. FIGS. 2A and 2B include features of the semiconductor device 200 that are related to a footing structure included in the semiconductor device 200 and may exclude other features of the semiconductor device 200 for clarity.

As shown in FIG. 2A, the semiconductor device 200 may include a memory array region 205 and an integrated circuit region 210. Furthermore, an insulative region 215 may be between the integrated circuit region 210 and the memory array region 205.

The memory array region 205 includes an array of active areas 220. Each active area 220 may be a semiconductor and may comprise, consist of, or consist essentially of semiconductive material. The semiconductive material may comprise, consist of, or consist essentially of silicon (e.g., polycrystalline silicon), a type III-V compound (e.g., gallium arsenide, gallium nitride, silicon germanium), and/or or another suitable semiconductive material, among other examples. In some implementations, an active area 220 corresponds to a channel of a transistor used to access a memory cell (e.g., a channel of the transistor 105 of FIG. 1).

As shown in FIG. 2A, the memory array region 205 includes an insulative fill 225 that surrounds (e.g., is around, over, and/or on) the array of active areas 220. The insulative fill 225 may be an electrical insulator and may comprise, consist of, or consist essentially of insulative material. The insulative material may comprise, consist of, or consist essentially of silicon dioxide, silicon nitride, and/or another suitable insulative material, among other examples. The insulative fill 225 may electrically isolate the array of active areas 220 to enable electrical functionality of the semiconductor device 200.

As shown in FIG. 2A, the integrated circuit region 210 (e.g., a core integrated circuit region) may include integrated circuitry 230. In addition to including combinations of semiconductive and insulative materials as described above, the integrated circuitry 230 may include conductive materials. The conductive materials may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), and/or a conductively-doped semiconductor material (e.g., conductively-doped silicon, conductively-doped germanium, and/or conductively-doped gallium arsenide), or another suitable conductive material, among other examples.

In some implementations, the integrated circuitry 230 is complementary metal oxide semiconductor (CMOS) integrated circuitry. Alternatively, and in some implementations, the integrated circuitry 230 is silicon germanium integrated circuitry, gallium nitride integrated circuitry, gallium arsenide integrated circuitry, or another type of suitable integrated circuitry, among other examples. The integrated circuitry 230 may include transistors, logic, sense amplifiers, and/or other integrated circuitry that supports functionality of the semiconductor device 200.

As shown in FIG. 2A, an array of digit line structures 235 may span across the memory array region 205 and portions of the insulative region 215. As described in greater detail in connection with FIG. 2B, each digit line structure 235 may be a multi-layer structure that includes a conductive line corresponding to a digit line (e.g., the digit line 120 of FIG. 1). In some implementations, a conductive line may electrically couple to an active area using a contact structure 240, thereby enabling electrical functionality of the semiconductor device 200.

As shown in FIG. 2B, a digit line structure 235 may include a conductive line 250 having a portion 255-1 (e.g., a first portion) that extends over a portion of the insulative region 215, and a portion 255-2 (e.g., a second portion) that extends over an opposite portion of the insulative region 215. The conductive line 250 may include a conductive material as described above and perform as a digit line of a memory cell (e.g., the digit line 120 of FIG. 1). A digit line structure 235 may further include dielectric portions 260 that are proximate opposing ends of the conductive line 250 and a capping/masking structure 265 that is over and/or on the conductive line 250. The dielectric portions 260 and/or the capping/masking structure 265 may include an insulative material as described above. Furthermore, the dielectric portions 260 and/or the capping/masking structure 265 may electrically isolate the conductive line 250 to enable functionality of the semiconductor device 200.

As further shown in FIG. 2B, a contact structure 240 may conjoin with the conductive line 250 and/or an active area 220, thereby electrically coupling the digit line structure 235 with the active area 220. Additionally, a footing structure 245 may conjoin with the conductive line 250 and penetrate into the insulative region 215, thereby anchoring the conductive line 250 (and/or the digit line structure 235) with the insulative region 215.

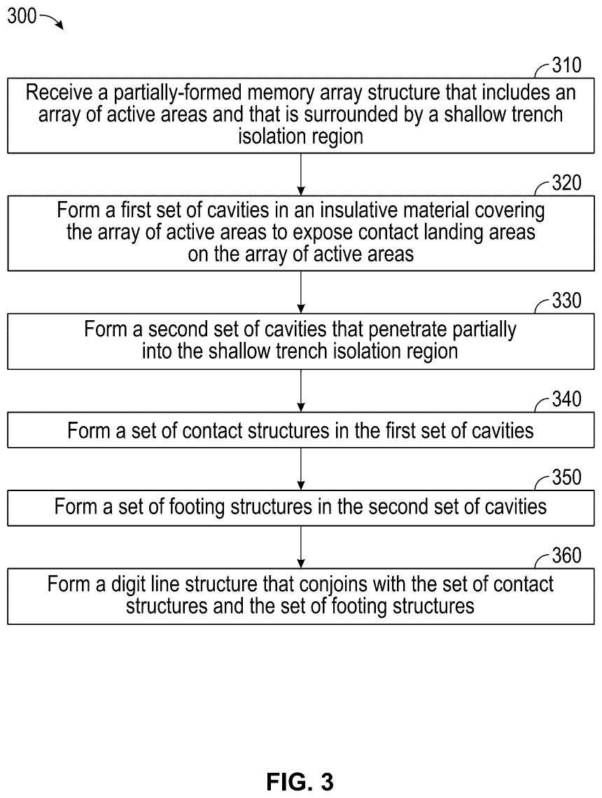

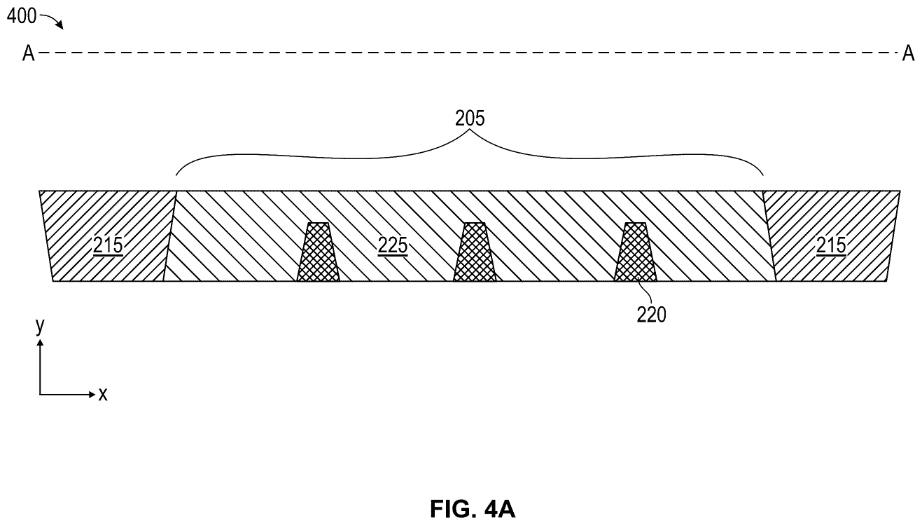

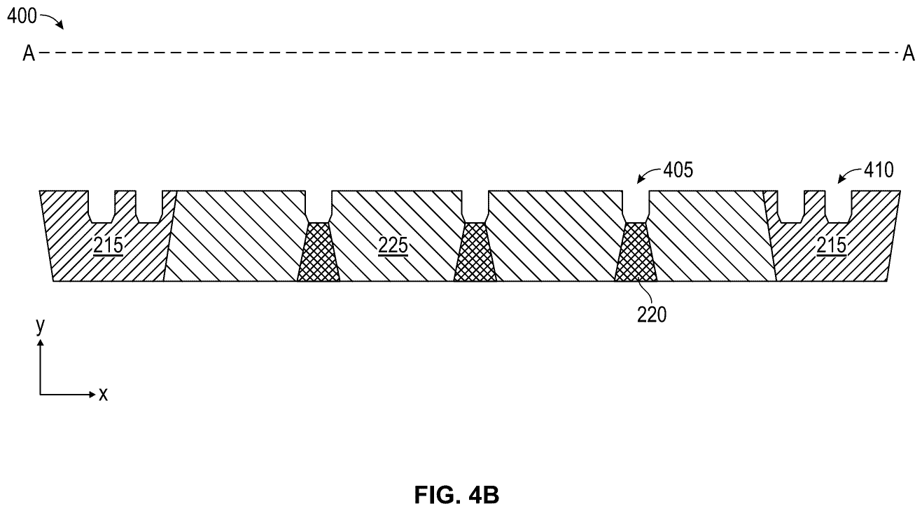

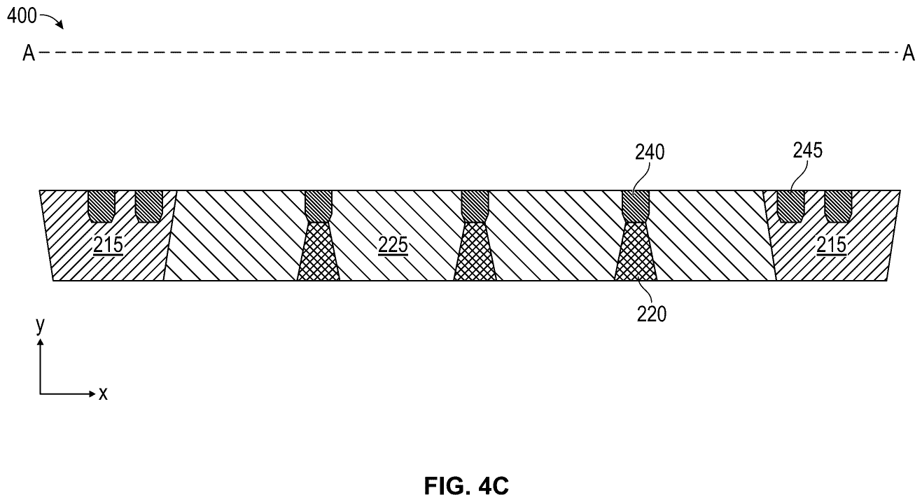

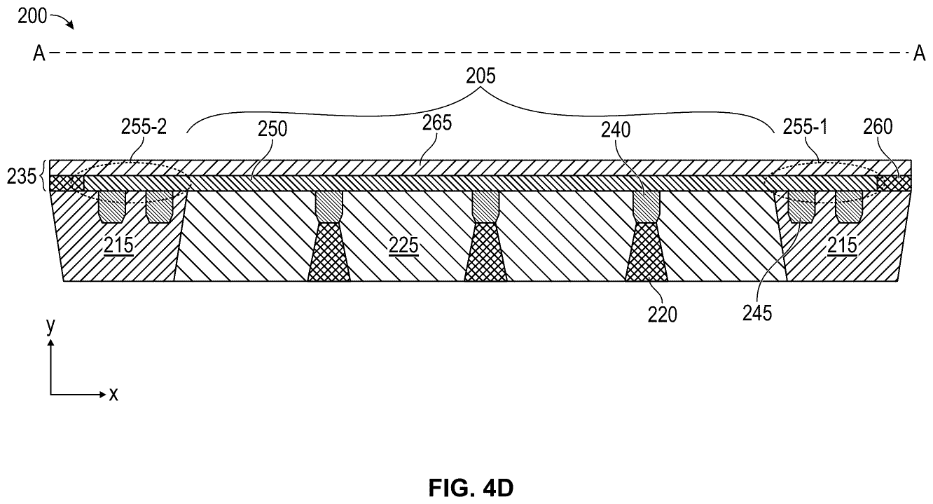

As described in greater detail in connection with FIGS. 3-4D, in some implementations, an array of footing structures 245 may fill cavities formed in the insulative region 215. In some implementations, the cavities may be treated (e.g., cleaned) and/or lined with an adhesion-promoting liner to increase an adhesion of the array of footing structures 245 to surfaces of the cavities. Additionally, or alternatively, in some implementations, surfaces of the array of footing structures 245 may be treated with silane, a self-assembled monolayer, or another chemical compound to increase bonding between the array of footing structures 245 and the array of digit lines 235.

In some implementations, the array of contact structures 240 and the array of footing structures 245 may include a same conductive material as described above. Additionally, or alternatively, in some implementations, the array of contact structures 240 and the array of footing structures 245 may include different conductive materials, as described above.

In some implementations, each contact structure 240 and each footing structure 245 may have a substantially similar size, geometric shape, and/or dimension. As an example, each contact structure 240 may have a geometric shape corresponding to a cylindrical post, a rectangular post, or a tapered post extending from the conductive line 250 a depth D1, and each footing structure 245 having the same geometric shape may extend from the conductive line a depth D2 that is approximately the same as the depth D1. In other words, the depth D2 and the depth D1 may be a same approximate depth.

Alternatively, in some implementations, one or more of the contact structures 240 and one or more of the footing structures 245 may have different sizes, shapes, and/or dimensions. As an example, a contact structures 240 may have a geometric shape corresponding to a cylindrical post, a rectangular post, or a tapered post extending from the conductive line 250 a depth D1, and a footing structure 245 may have a fin-like shape and/or a fin-like structure that extends from the conductive line a depth D2 that is greater than (or less than) the depth D1.

As indicated above, FIGS. 2A and 2B are provided as an example. Other examples may differ from what is described with regard to FIGS. 2A and 2B.

As described in connection with FIGS. 1, 2A, and 2B, in some implementations, an apparatus (e.g., the semiconductor device 200) includes a semiconductive region (e.g., the active area 220), an insulative region (e.g., the insulative region 215) that is adjacent to the semiconductive region, and a conductive line (e.g., the conductive line 250) that extends across the semiconductive region and at least a portion of the insulative region. The apparatus includes a contact structure (e.g., the contact structure 240) that conjoins with the conductive line and that electrically couples the conductive line with the semiconductive region. The apparatus includes a footing structure (e.g., the footing structure 245) that conjoins with the conductive line and that penetrates into the insulative region to anchor the conductive line with the insulative region.

Additionally, or alternatively, in some implementations, an integrated assembly (e.g., the semiconductor device 200) includes a memory array region (e.g., the memory array region 205) including an array of active areas (e.g., the array of active areas 220), a core integrated circuit region (e.g., the integrated circuit region 210) surrounding the memory array region, a shallow trench isolation region (e.g., the insulative region 215) that is between the memory array region and the core integrated circuit region, and an array of conductive lines (e.g., the array of digit line structure 235 including the conductive line(s) 250) extending across the memory array region. The array of digit line structures 235 includes first end regions (e.g., end regions 255-1 of the conductive line(s) 250) that extend over a first side region of the shallow trench isolation region, and second end regions (e.g., end regions 255-2 of the conductive line(s) 250) that extend over a second side region of the shallow trench isolation region, where the second side region is opposite the first side region. The integrated assembly includes contact structures (e.g., the array of contact structures 240) that electrically couple the array of conductive lines to the array of active areas and one or more footing structures (e.g., one or more of the array of footing structures 245) that penetrate into the first side region and the second side region to anchor the array of conductive lines with the shallow trench isolation region.

In these ways, the quality and/or reliability of the apparatus and/or the integrated assembly is improved. Since the quality and/or the reliability of the apparatus and/or the integrated assembly are improved, an amount of resources used to support a market consuming the apparatus and/or the integrated assembly (e.g., raw materials, semiconductor manufacturing tools, labor, and/or computing resources) is reduced, thus maintaining industry competitiveness without imposing extra resource expenditure.

FIG. 3 is a flowchart of an example method 300 of forming an integrated assembly or memory device having a footing structure. In some implementations, and as described in greater detail in connection with FIGS. 4A-4D, one or more process blocks of FIG. 3 may be performed by various semiconductor manufacturing equipment.

As shown in FIG. 3, the method 300 may include receiving a partially-formed memory array structure (e.g., the memory array region 205) that includes an array of active areas (e.g., the array of active areas 220) and that is surrounded by a shallow trench isolation region (e.g., the insulative region 215) (block 310). As further shown in FIG. 3, the method 300 may include forming a first set of cavities in an insulative material (e.g., the insulative fill 225) covering the array of active areas to expose contact landing areas on the array of active areas (block 320). As further shown in FIG. 3, the method 300 may include forming a second set of cavities that penetrate partially into the shallow trench isolation region (block 330). As further shown in FIG. 3, the method 300 may include forming a set of contact structures (e.g., the array of contact structures 240) in the first set of cavities (block 340). As further shown in FIG. 3, the method 300 may include forming a set of footing structures (e.g., the array of footing structures 245) in the second set of cavities (block 350). As further shown in FIG. 3, the method 300 may include forming a digit line structure (e.g., a digit line structure of the array of digit line structures 235) that conjoins with the set of contact structures and the set of footing structures (block 360).

The method 300 may include additional aspects, such as any single aspect or any combination of aspects described below and/or in connection with one or more other methods described elsewhere herein.

In a first aspect, forming the first set of cavities and forming the second set of cavities includes forming the first set of cavities and the second set of cavities simultaneously using a same etching operation.

In a second aspect, alone or in combination with the first aspect, forming the first set of cavities and forming the second set of cavities includes forming the first set of cavities and the second set of cavities using separate etching operations.

In a third aspect, alone or in combination with one or more of the first and second aspects, forming the set of contact structures and the set of footings includes forming the set of contact structures and the set of footings simultaneously using a same deposition operation.

In a fourth aspect, alone or in combination with one or more of the first through third aspects, forming the set of contact structures and the set of footings includes forming the set of contact structures and the set of footings using separate deposition operations.

In a fifth aspect, alone or in combination with one or more of the first through fourth aspects, forming the digit line structure includes forming a multi-layer digit line structure including a conductive line (e.g., the conductive line 250) that conjoins with the set of footing structures and the set of contact structures.

In a sixth aspect, alone or in combination with one or more of the first through fifth aspects, forming the second set of cavities includes treating surfaces of the second set of cavities using at least one of a plasma cleaning operation, a thermal annealing operation, a surface roughening operation, or an ultraviolet exposure operation.

In a seventh aspect, alone or in combination with one or more of the first through sixth aspects, forming the second set of cavities includes forming an adhesion promoting liner on surfaces of the second set of cavities.

In an eighth aspect, alone or in combination with one or more of the first through seventh aspects, forming the footing structures includes treating surfaces of the footing structures using at least one of a silane treatment operation, or a self-assembled monolayer treatment operation.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the footing structure 245, an integrated assembly that includes the footing structure 245, any part described herein of the footing structure 245, and/or any part described herein of an integrated assembly that includes the footing structure 245. For example, the method 300 may include forming one or more of the semiconductor device 200 or the memory array region 205.

FIGS. 4A-4D are diagrammatic views showing formation of footing structures (e.g., the array of footing structures 245) for a conductive line (e.g., the conductive line 250) at stages of an example process of forming the footing structures. In some implementations, the example process described below in connection with FIGS. 4A-4D may correspond to the method 300 and/or one or more blocks of the method 300. However, the process described below is an example, and other example processes may be used to form the footings, an integrated assembly that includes the footings, and/or one or more parts of the footings and/or the integrated assembly.

As shown in FIG. 4A, the process 400 may include a semiconductor tool (e.g., a photoresist dispense tool or a deposition tool, among other examples) receiving the memory array region 205 (e.g., a partially-formed memory array that does not include capacitors, among other examples). The memory array region 205, which may have been formed by a combination of semiconductor manufacturing tools being used to perform a series of deposition, lithography, and etch operations, is surrounded by the insulative region 215, and includes the array of active areas 220 that are surrounded and/or covered by the insulative fill 225.

As shown in FIG. 4B, the process 400 may include forming a set of cavities 405 (e.g., a first set of cavities) in the insulative fill 225 that expose contact landing areas on the array of active areas 220. As an example, forming the set of cavities 405 may include removing (e.g., etching) a portion of the insulative fill 225 to form the set of cavities 405. In some implementations, one or more masks may be used to form the cavities 405. For example, one or more masks may be deposited and/or patterned on the insulative fill 225 prior to removing material to form the cavities 405.

As further shown in FIG. 4B, the process 400 may include forming a set of cavities 410 (e.g., a second set of cavities) in the insulative fill 225 that penetrate partially into the insulative region 215. As an example, forming the set of cavities 410 may include removing (e.g., etching) a portion of the insulative fill 225 to form the set of cavities 410. In some implementations, one or more masks may be used to form the cavities 410. For example, one or more masks may be deposited and/or patterned on the insulative fill 225 prior to removing material to form the cavities 410.

In some implementations, the cavities 405 and the cavities 410 may be formed simultaneously. For example, and in a case where the cavities 405 and the cavities 410 are intended to be a same approximate size and/or shape (and the insulative region 215 and the insulative fill 225 include a same material), a same etching operation (and/or masking operation) may be used to form the cavities 405 and the cavities 410.

In some implementations, the cavities 405 and the cavities 410 may be formed using separate operations. For example, and in a case where the cavities 405 and the cavities 410 are to be different sizes and/or shapes (and/or the insulative region 215 and the insulative fill 225 different materials), different etching (and/or masking operations) may be used to form the cavities 405 and the cavities 410.

In some implementations, forming the cavities 410 includes treating surfaces of the cavities 410 to promote adhesion of a conductive material (e.g., a conductive material included in a footing structure 245) to the surfaces. As examples, treating the surfaces of the cavities 410 may include a plasma cleaning tool being used to perform a plasma cleaning operation, a furnace tool being used to perform an annealing operation, an etch tool being used to perform a surface roughening operation, or an ultraviolet ozone cleaning tool being used to perform an ultraviolet exposure operation to threat the surfaces.

Additionally, or alternatively and in some implementations, forming the cavities 410 includes forming an adhesion-promoting liner along surfaces of the cavities 410 that promotes adhesion of a conductive material (e.g., a conductive material include in a footing structure 245) to the surfaces. As an example, forming the adhesion-promoting liner along the surfaces of the cavities 410 may include a deposition tool being used to perform a deposition operation that deposits a titanium liner or a titanium nitride liner on the surfaces, among other examples.

As shown in FIG. 4C, the process 400 may include forming the array of contact structures 240. As an example, forming the array of contact structures 240 may include a deposition tool forming (e.g., depositing or growing) a conductive material as described above in the cavities 405. Additionally, or alternatively, forming the array of contact structures 240 may include a planarization tool being used to remove the excess conductive material that may be formed over the insulative region 215 and/or the insulative fill 225 using a chemical-mechanical polishing operation, among other examples.

As further shown in FIG. 4C, the process 400 may include forming the array of footing structures 245. As an example, forming the array of footing structures 245 may include a deposition tool forming (e.g., depositing or growing) a conductive material as described above in the cavities 410. Additionally, or alternatively, forming the array of footing structures 245 may include a planarization tool being used to remove the excess conductive material that may be formed over the insulative region 215 and/or the insulative fill 225 using a chemical-mechanical polishing operation, among other examples.

In some implementations, the array of contact structures 240 and the array of footing structures 245 may be formed simultaneously. For example, and in a case where the array of contact structures 240 and the array of footing structures 245 include a same conductive material, a deposition tool may be used to perform a single (e.g., a same) deposition operation that forms the array of contact structures 240 and the array of footing structures 245.

In some implementations, the array of contact structures 240 and the array of footing structures 245 may be formed using separate operations. For example, and in a case where the array of contact structures 240 and the array of footing structures 245 include different conductive materials, a deposition tool may be used to perform a first deposition operation that forms the array of contact structures 240 and a second deposition operation that forms the array of footing structures 245.

In some implementations, forming the array of contact structures 240 and/or the array of footing structures 245 includes treating surfaces of the array of contact structures 240 and/or surfaces of the footing structures 245 with an agent that promotes adhesion of a conductive material (e.g., a conductive material included in the array of contact structures 240 and/or the footing structures) to the surfaces. As examples, treating the treating surfaces of the array of contact structures 240 and/or surfaces of the array of footing structures 245 may include a dispense tool being used to perform a treatment operation that sprays silane or a self-assembled monolayer on the surfaces of the array of contact structures 240 and/or the surfaces of the footing structures 245.

As shown in FIG. 4D, the process 400 may include forming the array of digit line structures 235 across the memory array region 205, including the portions 255-1 and 255-2 of the conductive line 250 that extend over the insulative region 215. As an example, in some implementations, forming the array of digit line structures 235 may include a deposition tool being used to form (e.g., deposit, grow) the conductive line 250, the dielectric portions 260, and/or the capping/masking structure 265 using a series of one or more deposition operations.

As indicated above, the process steps described in connection with FIGS. 4A-4D are provided as examples. Other examples may differ from what is described with respect to FIGS. 4A-4D. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

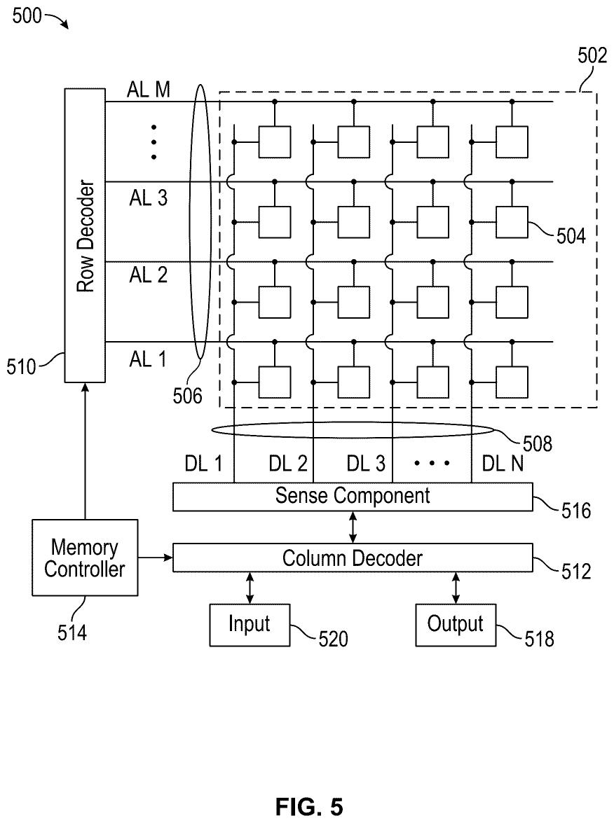

FIG. 5 is a diagrammatic view of an example memory device 500 described herein. The memory device 500 may include a memory array 502 that includes multiple memory cells 504. A memory cell 504 is programmable or configurable into a data state of multiple data states (e.g., two or more data states). For example, a memory cell 504 may be set to a particular data state at a particular time, and the memory cell 504 may be set to another data state at another time. A data state may correspond to a value stored by the memory cell 504. The value may be a binary value, such as a binary 0 or a binary 1, or may be a fractional value, such as 0.5, 1.5, or the like. A memory cell 504 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 504 by activating or selecting the appropriate access line 506 (shown as access lines AL 1 through AL M) and digit line 508 (shown as digit lines DL 1 through DL N). An access line 506 may also be referred to as a “row line” or a “word line,” and a digit line 508 may also be referred to a “column line” or a “bit line.” Activating or selecting an access line 506 or a digit line 508 may include applying a voltage to the respective line. An access line 506 and/or a digit line 508 may comprise, consist of, or consist essentially of a conductive material, such as a metal (e.g., copper, aluminum, gold, titanium, or tungsten) and/or a metal alloy, among other examples. In FIG. 5, each row of memory cells 504 is connected to a single access line 506, and each column of memory cells 504 is connected to a single digit line 508. By activating one access line 506 and one digit line 508 (e.g., applying a voltage to the access line 506 and digit line 508), a single memory cell 504 may be accessed at (e.g., is accessible via) the intersection of the access line 506 and the digit line 508. The intersection of the access line 506 and the digit line 508 may be called an “address” of a memory cell 504.

In some implementations, the logic storing device of a memory cell 504, such as a capacitor, may be electrically isolated from a corresponding digit line 508 by a selection component, such as a transistor. The access line 506 may be connected to and may control the selection component. For example, the selection component may be a transistor, and the access line 506 may be connected to the gate of the transistor. Activating the access line 506 results in an electrical connection or closed circuit between the capacitor of a memory cell 504 and a corresponding digit line 508. The digit line 508 may then be accessed (e.g., is accessible) to either read from or write to the memory cell 504.

A row decoder 510 and a column decoder 512 may control access to memory cells 504. For example, the row decoder 510 may receive a row address from a memory controller 514 and may activate the appropriate access line 506 based on the received row address. Similarly, the column decoder 512 may receive a column address from the memory controller 514 and may activate the appropriate digit line 508 based on the column address.

Upon accessing a memory cell 504, the memory cell 504 may be read (e.g., sensed) by a sense component 516 to determine the stored data state of the memory cell 504. For example, after accessing the memory cell 504, the capacitor of the memory cell 504 may discharge onto its corresponding digit line 508. Discharging the capacitor may be based on biasing, or applying a voltage, to the capacitor. The discharging may induce a change in the voltage of the digit line 508, which the sense component 516 may compare to a reference voltage (not shown) to determine the stored data state of the memory cell 504. For example, if the digit line 508 has a higher voltage than the reference voltage, then the sense component 516 may determine that the stored data state of the memory cell 504 corresponds to a first value, such as a binary 1. Conversely, if the digit line 508 has a lower voltage than the reference voltage, then the sense component 516 may determine that the stored data state of the memory cell 504 corresponds to a second value, such as a binary 0. The detected data state of the memory cell 504 may then be output (e.g., via the column decoder 512) to an output component 518 (e.g., a data buffer). A memory cell 504 may be written (e.g., set) by activating the appropriate access line 506 and digit line 508. The column decoder 512 may receive data, such as input from input component 520, to be written to one or more memory cells 504. A memory cell 504 may be written by applying a voltage across the capacitor of the memory cell 504.

The memory controller 514 may control the operation (e.g., read, write, re-write, refresh, and/or recovery) of the memory cells 504 via the row decoder 510, the column decoder 512, and/or the sense component 516. The memory controller 514 may generate row address signals and column address signals to activate the desired access line 506 and digit line 508. The memory controller 514 may also generate and control various voltages used during the operation of the memory array 502.

In some implementations, the memory device 500 includes the footing structure 245 and/or an integrated assembly that includes the footing structure 245. For example, the memory array 502 may include the footing structure 245 and/or an integrated assembly that includes the footing structure 245. Additionally, or alternatively, the memory cell 504 may include a memory cell described elsewhere herein.

As indicated above, FIG. 5 is provided as an example. Other examples may differ from what is described with respect to FIG. 5.

In some implementations, an apparatus includes a semiconductive region; an insulative region that is adjacent to the semiconductive region; a conductive line that extends across the semiconductive region and at least a portion of the insulative region; a contact structure that conjoins with the conductive line and that electrically couples the conductive line with the semiconductive region; and a footing structure that conjoins with the conductive line and that penetrates into the insulative region to anchor the conductive line with the insulative region.

In some implementations, an integrated assembly includes a memory array region comprising an array of active areas; a core integrated circuit region surrounding the memory array region; a shallow trench isolation region that is between the memory array region and the core integrated circuit region; an array of conductive lines extending across the memory array region, comprising: first end regions that extend over a first side region of the shallow trench isolation region; and second end regions that extend over a second side region of the shallow trench isolation region, wherein the second side region is opposite the first side region; contact structures that electrically couple the array of conductive lines to the array of active areas; and one or more footing structures that penetrate into the first side region and the second side region to anchor the array of conductive lines with the shallow trench isolation region.

In some implementations, a method includes receiving a partially-formed memory array structure that includes an array of active areas and that is surrounded by a shallow trench isolation region; forming a first set of cavities in an insulative material covering the array of active areas to expose contact landing areas on the array of active areas; forming a second set of cavities that penetrate partially into the shallow trench isolation region; forming a set of contact structures in the first set of cavities; forming a set of footing structures in the second set of cavities; and forming a digit line structure that conjoins with the set of contact structures and the set of footing structures.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An apparatus, comprising:
a semiconductive region;
an insulative region that is adjacent to the semiconductive region;
a conductive line that extends across the semiconductive region and at least a portion of the insulative region;
a contact structure that conjoins with the conductive line and that electrically couples the conductive line with the semiconductive region; and
a footing structure that conjoins with the conductive line and that penetrates into the insulative region to anchor the conductive line with the insulative region.

2. The apparatus of claim 1, wherein the contact structure and the footing structure are a same approximate size and shape.

3. The apparatus of claim 1, wherein the conductive line, the contact structure, and the footing structure comprise a same conductive material.

4. The apparatus of claim 1, wherein a shape of the footing structure approximates:
a cylindrical post, or
a rectangular post, or
a tapered post.

5. The apparatus of claim 1, wherein the footing structure is a fin-like structure.

6. The apparatus of claim 1, wherein the footing structure comprises a first conductive material and the conductive line comprises a second, different conductive material.

7. An integrated assembly, comprising:
a memory array region comprising an array of active areas;
a core integrated circuit region surrounding the memory array region;
a shallow trench isolation region that is between the memory array region and the core integrated circuit region;
an array of conductive lines extending across the memory array region, comprising:
first end regions that extend over a first side region of the shallow trench isolation region; and
second end regions that extend over a second side region of the shallow trench isolation region,
wherein the second side region is opposite the first side region;
contact structures that electrically couple the array of conductive lines to the array of active areas; and
one or more footing structures that penetrate into the first side region and the second side region to anchor the array of conductive lines with the shallow trench isolation region.

8. The integrated assembly of claim 7, wherein the footing structures fill cavities in the shallow trench isolation region that are lined with an adhesion promoting liner.

9. The integrated assembly of claim 7, wherein the contact structures and the footing structures extend from the conductive lines a same, approximate depth.

10. The integrated assembly of claim 7, wherein the contact structures extend from the conductive lines a first depth and the footing structures extend from the conductive lines a second depth that is greater than the first depth.

11. The integrated assembly of claim 7, wherein the contact structures extend from the conductive lines a first depth and the footing structures extend from the conductive lines a second depth that is less than the first depth.

12. A method, comprising:
receiving a partially-formed memory array structure that includes an array of active areas and that is surrounded by a shallow trench isolation region;
forming a first set of cavities in an insulative material covering the array of active areas to expose contact landing areas on the array of active areas;
forming a second set of cavities that penetrate partially into the shallow trench isolation region;
forming a set of contact structures in the first set of cavities;
forming a set of footing structures in the second set of cavities; and
forming a digit line structure that conjoins with the set of contact structures and the set of footing structures.

13. The method of claim 12, wherein forming the first set of cavities and forming the second set of cavities includes:
forming the first set of cavities and the second set of cavities simultaneously using a same etching operation.

14. The method of claim 12, wherein forming the first set of cavities and forming the second set of cavities includes:
forming the first set of cavities and the second set of cavities using separate etching operations.

15. The method of claim 12, wherein forming the set of contact structures and the set of footings includes:
forming the set of contact structures and the set of footings simultaneously using a same deposition operation.

16. The method of claim 12, wherein forming the set of contact structures and the set of footings includes:
forming the set of contact structures and the set of footings using separate deposition operations.

17. The method of claim 12, wherein forming the digit line structure includes:
forming a multi-layer digit line structure including a conductive line that conjoins with the set of footing structures and the set of contact structures.

18. The method of claim 12, wherein forming the second set of cavities includes treating surfaces of the second set of cavities using at least one of:
a plasma cleaning operation,
a thermal annealing operation,
a surface roughening operation, or
an ultraviolet exposure operation.

19. The method of claim 12, wherein forming the second set of cavities includes:
forming an adhesion promoting liner on surfaces of the second set of cavities.

20. The method of claim 12, wherein forming the footing structures includes treating surfaces of the footing structures using at least one of
a silane treatment operation, or
a self-assembled monolayer treatment operation.
